(19) United States
(12) Patent Application Publication
(10) Pub. No.: US 2023/0096472 A1
(43) Pub. Date: Mar. 30, 2023

(54) METHOD FOR MANUFACTURING PHOTOSENSITIVE RESIN COMPOSITION

(71) Applicant: SUMITOMO BAKELITE CO., LTD., Tokyo (JP)

(72) Inventors: Ryuji HIROSAWA, Tokyo (JP); Sakiko SUZUKI, Tokyo (JP); Taro KITAHATA, Tokyo (JP); Makoto HORII, Tokyo (JP)

(73) Assignee: SUMITOMO BAKELITE CO., LTD., Tokyo (JP)

(21) Appl. No.: 17/801,127

(22) PCT Filed: Feb. 19, 2021
(86) PCT No.: PCT/JP2021/006410

§ 371 Date: Aug. 19, 2022

(30) Foreign Application Priority Data
Feb. 20, 2020 (JP) 2020-026930

(51) Int. Cl. C08G 69/36

(52) U.S. Cl. CPC C08G 69/36

(57) ABSTRACT

The method for manufacturing a photosensitive resin composition of the present invention is a method for manufacturing a photosensitive resin composition containing an amide bond-containing precursor having a repeating unit represented by General Formula (1), the method including a step of obtaining an activated carboxylic acid material by activating a carboxylic acid compound represented by General Formula (2) and a step of obtaining the amide bond-containing precursor by allowing an amine compound represented by General Formula (3) to act on the activated carboxylic acid material, in which at least either the step of obtaining an activated carboxylic acid material and the step of obtaining the amide bond-containing precursor is performed in a solvent containing a carbonyl group-containing heterocyclic compound.

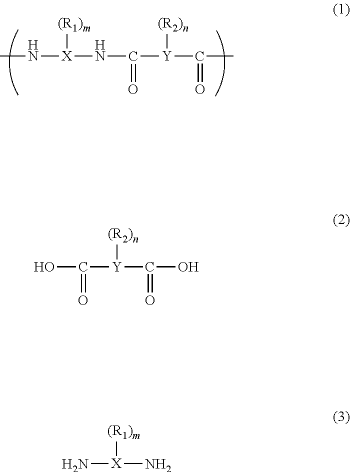

### FIELD OF THE INVENTION

The present invention relates to a method for manufacturing a photosensitive resin composition.

### BACKGROUND OF THE INVENTION

Conventionally, as a surface protection film or an interlayer insulating film of a semiconductor element, owing to high heat resistance, excellent electrical characteristics, and excellent mechanical characteristics, a polyamide resin having a specific structure has been preferably used. In a case where the polyamide resin is used as a protection film or an interlayer insulating film of a semiconductor element, from the viewpoint of improving the efficiency of the process, generally, the polyamide resin is used in the form of varnish by being dissolved in an organic solvent.

Regarding the polyamide resin, the technique disclosed in Patent Document 1 is known. Patent Document 1 discloses a photosensitive resin composition obtained by combining a polyimide precursor or a polybenzoxazole precursor and a polar solvent having a specific structure, in which the content of N-methyl-2-pyrrolidone in the photosensitive resin composition is adjusted to be equal to or less than 0.1% by mass so that the obtained resin composition does not turn into a gel with the passage of time and is satisfactory in sensitivity and mechanical characteristics.

### RELATED DOCUMENT

### Patent Document

[Patent Document 1] International Publication No. WO2014/115233

### DISCLOSURE OF THE INVENTION

### Problem to be Solved by the Invention

In Patent Document 1, from the viewpoint of reducing the environmental load, an appropriate solvent or the like is selected so that the content of N-methyl-2-pyrrolidone in the resin composition is reduced.

However, at the stage of preparing a resin described in Synthesis Example 1 of Patent Document 1 or the like, the N-methyl-2-pyrrolidone is used as a so-called synthetic solvent. In addition to this, in order to reduce N-methyl-2-pyrrolidone after the reaction, an operation of washing an organic layer is also performed.

This operation complicates the process, and in a case where scale-up is carried out, there is a concern that N-methyl-2-pyrrolidone may remain.

The present invention takes the above circumstances into consideration and provides a manufacturing method that makes it possible to stably obtain a photosensitive resin composition imposing less environmental load.

### Means for Solving Problem

According to the present invention,

there is provided a method for manufacturing a photosensitive resin composition containing an amide bond-containing precursor having a repeating unit represented by General Formula (1), the method including a step of obtaining an activated carboxylic acid material by activating a carboxylic acid compound represented by General Formula (2), and

a step of obtaining the amide bond-containing precursor by allowing an amine compound represented by General Formula (3) to act on the activated carboxylic acid material,

in which at least either the step of obtaining an activated carboxylic acid material or the step of obtaining an amide bond-containing precursor is performed in a solvent containing a carbonyl group-containing heterocyclic compound.

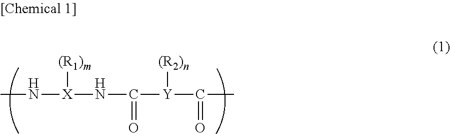

(In General Formula (1), each of X and Y is an organic group. R₁ is a hydroxyl group, —O—R₃, an alkyl group, an acyloxy group, or a cycloalkyl group, and a plurality of R₁'s may be the same as or different from each other in a case where the repeating unit has the plurality of R₁'s. R₂ is a hydroxyl group, a carboxyl group, —O—R₃, or —COO—R₃, and a plurality of R₂'s may be the same as or different from each other in a case where the repeating unit has the plurality of R₂'s. R₃ in R₁ and R₂ is an organic group having 1 to 15 carbon atoms. In a case where there is no hydroxyl group as R₁, at least one of R₂'s is a carboxyl group. In a case where there is no carboxyl group as R₂, at least one of R₁'s is a hydroxyl group. m is an integer of 0 to 8, and n is an integer of 0 to 8.)

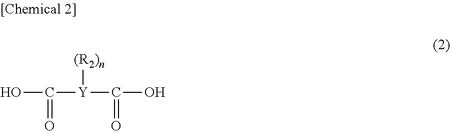

(Y, R₂, and n in General Formula (2) have the same definition as Y, R₂, and n in General Formula (1).)

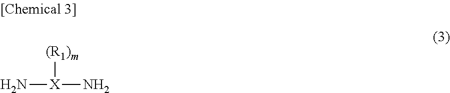

(X, R₁, and m in General Formula (3) have the same definition as X, R₁, and m in General Formula (1).)

### Advantage of the Invention

According to the present invention, it is possible to stably obtain a photosensitive resin composition that less imposes the environmental load.

### BRIEF DESCRIPTION OF THE DRAWINGS

FIG. 1 is a cross-sectional view showing an example of an electronic device according to the present embodiment.

### MODE FOR CARRYING OUT THE INVENTION

Hereinafter, embodiments will be described with reference to drawings as appropriate. In all drawings, the same constituents will be marked with the same reference numerals, and the description thereof will not be repeated. In addition, unless otherwise specified, “to” means “equal to or more than what precedes to and equal to or less than what follows to”.

[Method for Manufacturing Photosensitive Resin Composition]

The method for manufacturing a photosensitive resin composition according to the present embodiment is the following method.

A method for manufacturing a photosensitive resin composition containing an amide bond-containing precursor having a repeating unit represented by General Formula (1), the method including

a step of obtaining an activated carboxylic acid material by activating a carboxylic acid compound represented by General Formula (2), and
a step of obtaining the amide bond-containing precursor by allowing an amine compound represented by General Formula (3) to act on the activated carboxylic acid material,
in which at least either the step of obtaining an activated carboxylic acid material or the step of obtaining an amide bond-containing precursor is performed in a solvent containing a carbonyl group-containing heterocyclic compound.

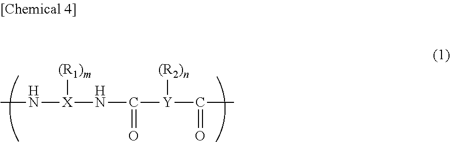

(In General Formula (1), each of X and Y is an organic group. R₁ is a hydroxyl group, —O—R₃, an alkyl group, an acyloxy group, or a cycloalkyl group, and a plurality of R₁'s may be the same as or different from each other in a case where the repeating unit has the plurality of R₁'s. R₂ is a hydroxyl group, a carboxyl group, —O—R₃, or —COO—R₃, and a plurality of R₂'s may be the same as or different from each other in a case where the repeating unit has the plurality of R₂'s. R₃ in R₁ and R₂ is an organic group having 1 to 15 carbon atoms. In a case where there is no hydroxyl group as R₁, at least one of R₂'s is a carboxyl group. In a case where there is no carboxyl group as R₂, at least one of R₁'s is a hydroxyl group. m is an integer of 0 to 8, and n is an integer of 0 to 8.)

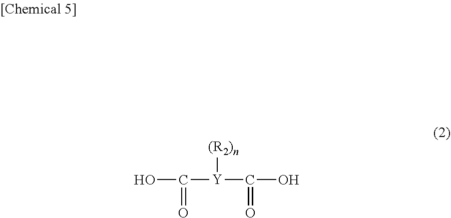

(Y, R₂, and n in General Formula (2) have the same definition as Y, R₂, and n in General Formula (1).)

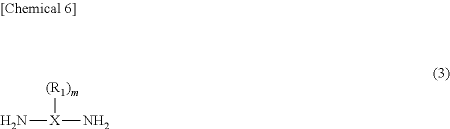

(X, R₁, and m in General Formula (3) have the same definition as X, R₁, and m in General Formula (1).)

(Amide Bond-Containing Precursor)

First, the amide bond-containing precursor contained in the photosensitive resin composition manufactured by the manufacturing method of the present embodiment will be described.

In the present embodiment, the amide bond-containing precursor has a structure represented by General Formula (1) (hereinafter, this precursor will be also called “polyamide resin”). As R₁ and R₂ in General Formula (1), in order to adjust the solubility of the polyamide resin in an aqueous alkali solution, groups obtained by protecting a hydroxyl group and a carboxyl group with a protecting group R₃ can be used. Specifically, —O—R₃ can be used as R₁, and —O—R₃ and —COO—R₃ can be used as R₂. Examples of organic groups having 1 to 15 carbon atoms as R₃ include a formyl group, a methyl group, an ethyl group, a propyl group, an isopropyl group, a tertiary butyl group, a tertiary butoxycarbonyl group, a phenyl group, a benzyl group, a tetrahydrofuranyl group, a tetrahydropyranyl group, and the like.

The organic group as X in the General Formula (1) is not particularly limited. Examples of the organic group include an aromatic group including a structure such as a benzene ring, a naphthalene ring, or a bisphenol structure; a heterocyclic organic group including a structure such as a pyrrole ring or a furan ring; a siloxane group, and the like. More specifically, an organic group represented by Formula (12) is preferable. As necessary, one kind of each of these organic groups may be used, or two or more kinds of these organic groups may be used in combination.

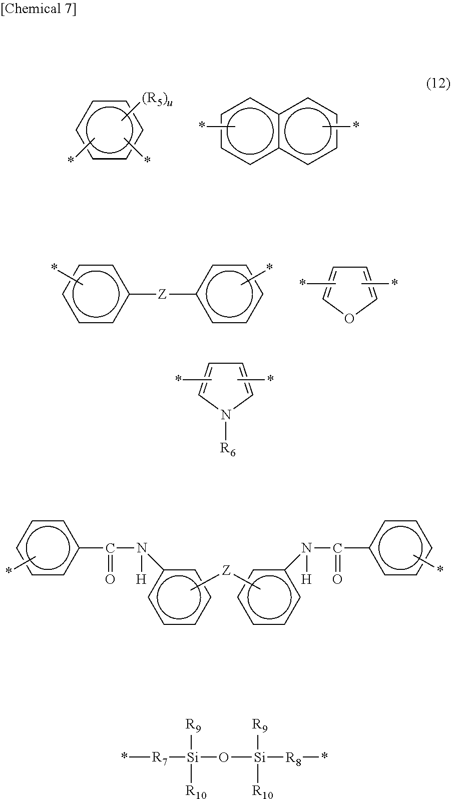

(In Formula (12), * represents a position bonded to the NH group in General Formula (1). Z is an alkylene group, a substituted alkylene group, —O—C₆H₄—O—, —O—, —S—, —SO₂—, —C(═O)—, —NHC(═O)—, or a single bond. R₅'s each represent one selected from an alkyl group, an alkyl ester group, and a halogen atom, and may be the same as or different from each other. R₆ represents one selected from a hydrogen atom, an alkyl group, an alkyl ester group, and a halogen atom. u is an integer of 0 to 4. Each of R₇ to R₁₀ is a monovalent or divalent organic group.

Note that the substituent R₁ of X in General Formula (1) is not shown in the Formula (12).)

Among the groups represented by Formula (12), for example, the groups represented by Formula (13) (some of these groups have R₁ in General Formula (1)) are particularly preferable.

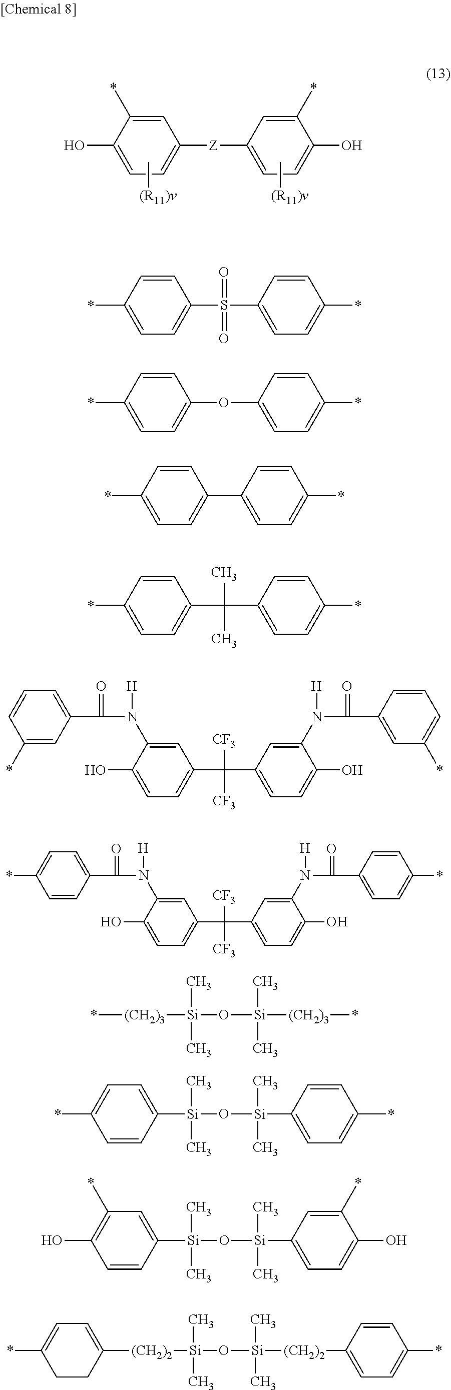

(In Formula (13), * represents a position bonded to the NH group in General Formula (1). In this formula, Z is an alkylene group, a substituted alkylene group, —O—, —S—, —SO₂—, —C(═O)—, —NHC(═O)—, —CH₃—, —C(CH₃)H—, —C(CH₃)₂—, —C(CF₃)₂—, or a single bond. R₁₁ is one selected from an alkyl group, an alkoxy group, an acyloxy group, and a cycloalkyl group, and a plurality of R₁₁'s may be the same as or different from each other in a case where there is a plurality of R₁₁'s. v is an integer equal to or more than 0 and equal to or less than 3.)

Among the groups represented by Formula (13), for example, the groups represented by Formula (14) (some of these groups have R₁ in General Formula (1)) are particularly preferable.

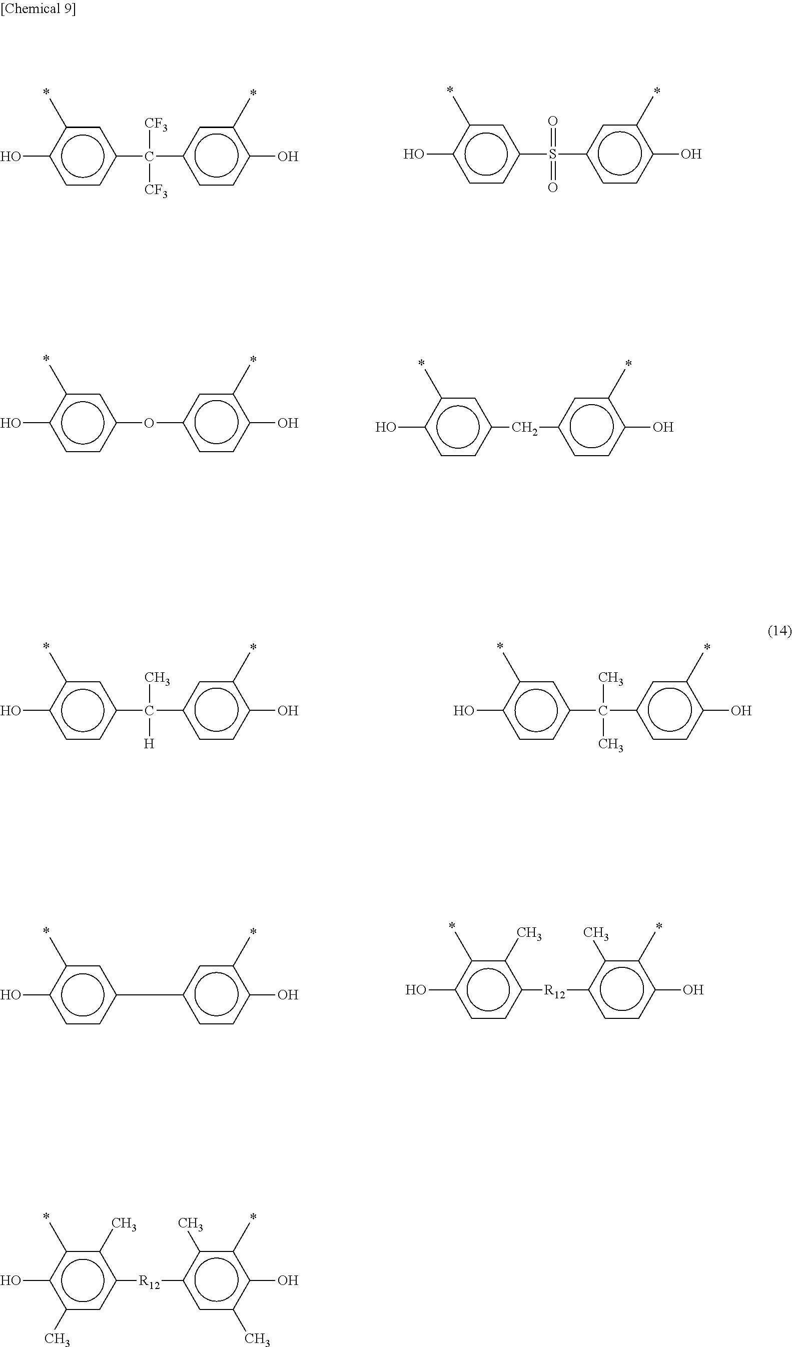

(In Formula (14), * represents a position bonded to the NH group in General Formula (1). R₁₂ is an organic group selected from an alkylene group, a substituted alkylene group, —O—, —S—, —SO₂—, —C(═O)—, —NHC(═O)—, —C(CF₃)₂—, and a single bond.)

Specific examples of the alkylene group and the substituted alkylene group as Z in Formulas (12) and (13) and R₁₂ in Formula (14) include —CH₂—, —CH(CH₃)—, —C(CH₃)₂—, —CH(CH₂CH₃)—, —C(CH₃) (CH₂CH₃)—, —C(CH₂CH₃) (CH₂CH₃)—, —CH(CH₂CH₂CH₃)—, —C(CH₃) (CH₂CH₂CH₃)—, —CH(CH(CH₃)₂)—, —C(CH₃) (CH(CH₃)₂)—, —CH(CH₂CH₂CH₂CH₃)—, —C(CH₃) (CH₂CH₂CH₂CH₃)—, —CH(CH₂CH(CH₃)₂)—, —C(CH₃) (CH₂CH(CH₃)₂)—, —CH(CH₂CH₂CH₂CH₂CH₃)—, —C(CH₃) (CH₂CH₂CH₂CH₂CH₃)—, —CH(CH₂CH₂CH₂CH₂CH₂CH₃)—, —C(CH₃) (CH₂CH₂CH₂CH₂CH₂CH₃)—, and the like. Among these, —CH₂—, —CH(CH₃)—, and —C(CH₃)₂— are preferable because these groups exhibit sufficient solubility not only in an aqueous alkali solution but also in a solvent and make it possible to obtain a well-balanced resin film.

Y in General Formula (1) is an organic group, and examples of the organic group are the same as the examples of X described above. Examples of the organic group include an aromatic group including a structure such as a benzene ring, a naphthalene ring, or a bisphenol structure; a heterocyclic organic group including a structure such as a pyrrole ring, a pyridine ring, or a furan ring; a siloxane group, and the like. More specifically, for example, an organic group represented by Formula (15) is preferable. One kind of each of these organic groups may be used, or two or more kinds of these organic groups may be used in combination.

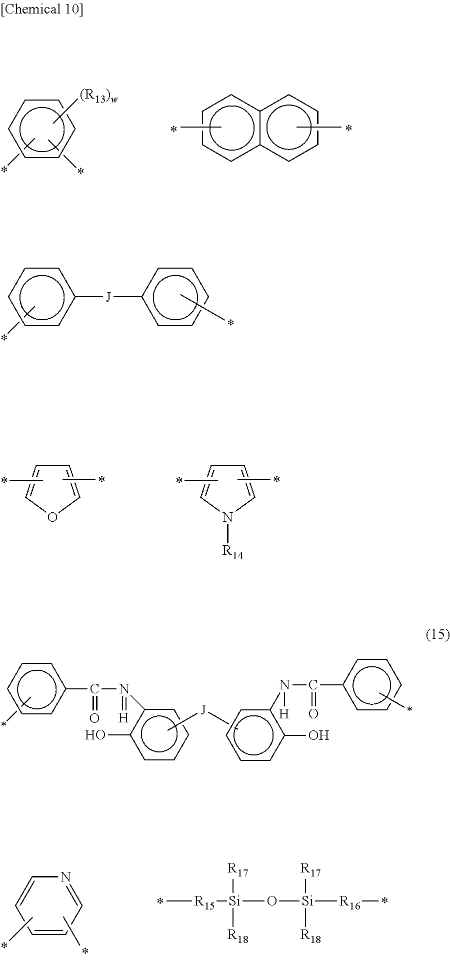

(In Formula (15), * represents a position bonded to the C═O group in General Formula (1). J is —CH₂—, —C(CH₃)₂—, —O—, —S—, —SO₂—, —C(═O)—, —NHC(═O)—, —C(CF₃)₂—, or a single bond. R₁₃'s each represent one selected from an alkyl group, an alkyl ester group, an alkyl ether group, a benzyl ether group, and a halogen atom, and may be the same as or different from each other. R₁₄ represents one selected from a hydrogen atom, an alkyl group, an alkyl ester group, and a halogen atom. w is an integer equal to or more than 0 and equal to or less than 2. Each of R₁₅ to R₁₈ is a monovalent or divalent organic group.

Note that the substituent R₂ of Y in General Formula (1) is not shown in Formula (15).)

Among the groups represented by Formula (15), for example, the groups represented by Formula (16) (some of these groups have R₂ in General Formula (1)) are particularly preferable.

Examples of the structure derived from tetracarboxylic dianhydride in Formula (16) include a structure bonded to the C═O groups in General Formula (1) at meta-positions for both the C═O groups and a structure bonded to the C═O groups in General Formula (1) at para-positions for both the C═O groups. The structure may include meta-position and para-position as bonding positions.

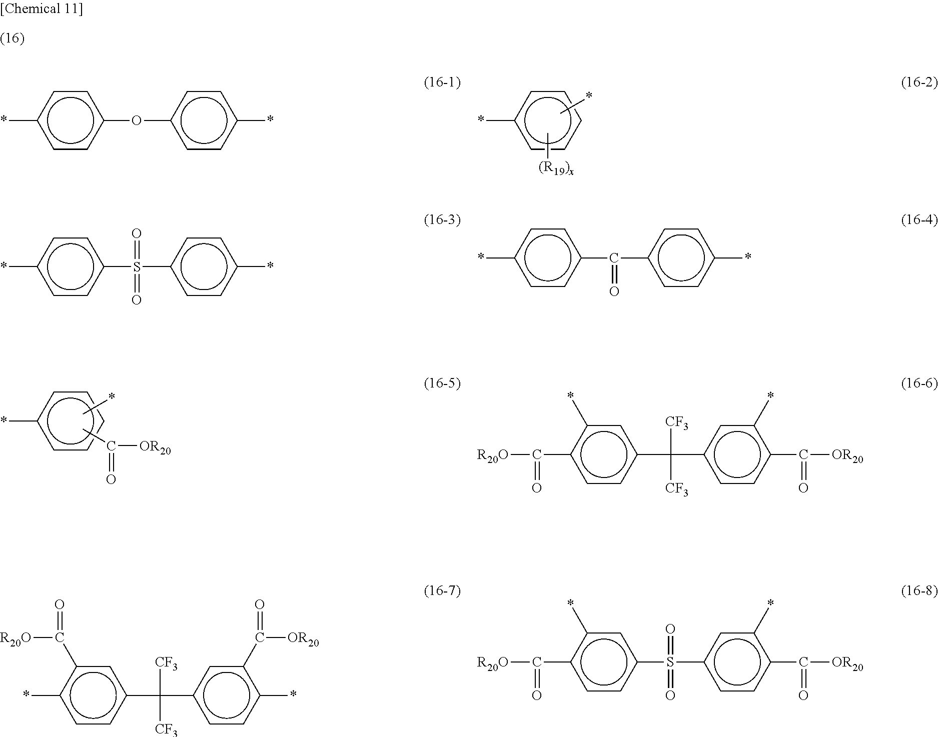

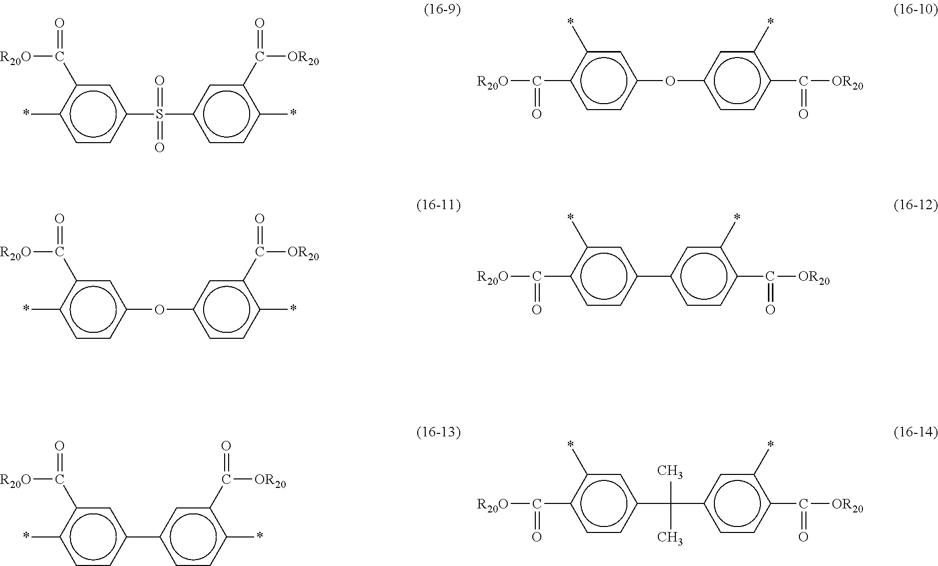

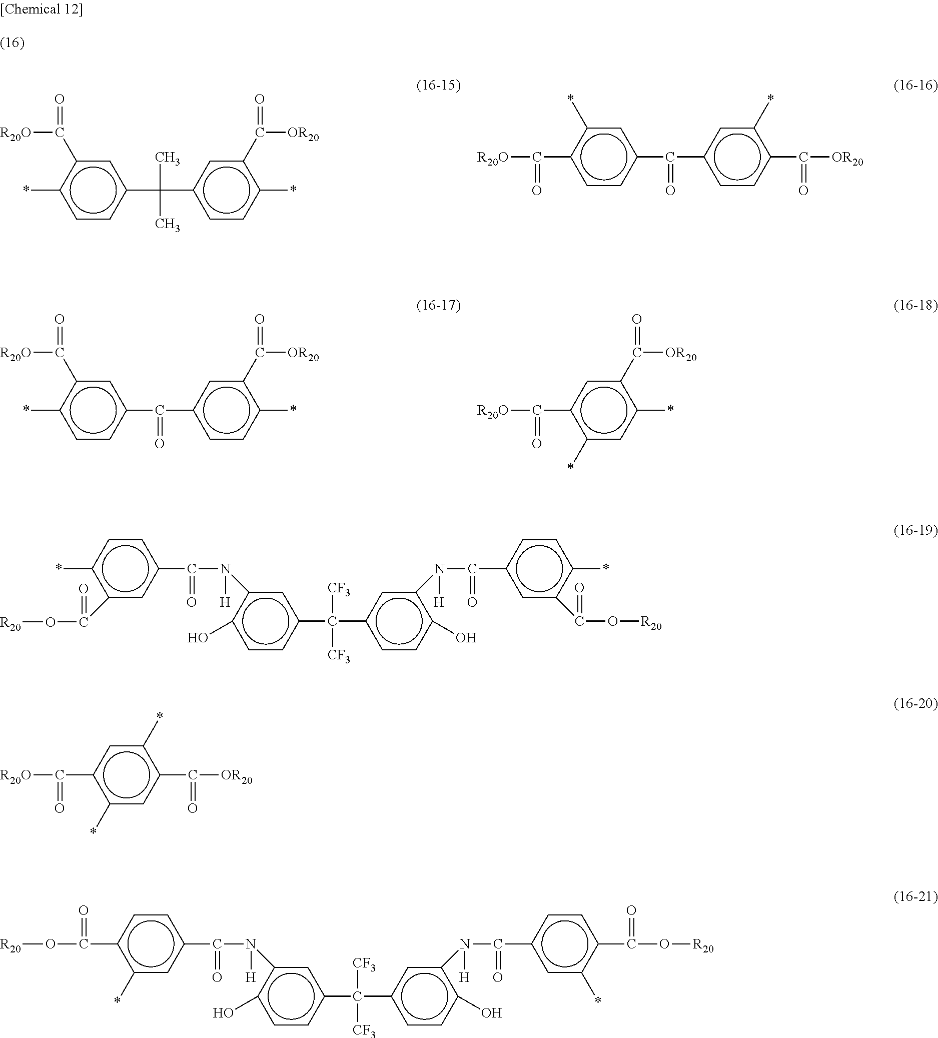

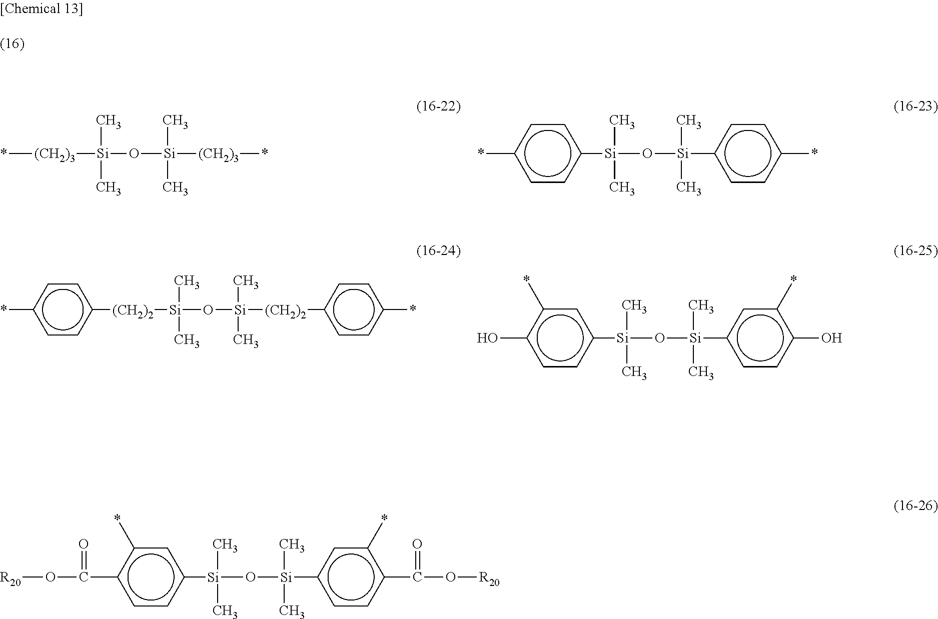

(In Formula (16), * represents a position bonded to the C═O group in General Formula (1). R₁₉'s each represent one selected from an alkyl group, an alkyl ester group, an alkyl ether group, a benzyl ether group, and a halogen atom, and may be the same as or different from each other. R₂₀ represents one selected from a hydrogen atom and an organic group having 1 or more and 15 or less carbon atoms, and may be partially substituted. x is an integer equal to or more than 0 and equal to or less than 2.)

In the present embodiment, the aforementioned amide bond-containing precursor is prepared through the following steps.

(Step 1) a step of obtaining an activated carboxylic acid material by activating a carboxylic acid compound represented by General Formula (2).

(Step 2) a step of obtaining an amide bond-containing precursor by allowing an amine compound represented by General Formula (3) to act on the activated carboxylic acid material.

That is, in the present embodiment, the molecules of the carboxylic acid compound represented by General Formula (2) are appropriately converted, and then the compound is condensed with the amine compound represented by General Formula (3), so that a desired amide bond-containing precursor is obtained.

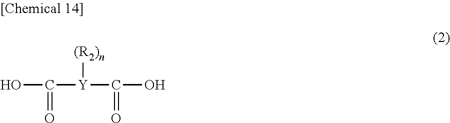

(Y, R₂, and n in General Formula (2) have the same definition as Y, R₂, and n in General Formula (1).)

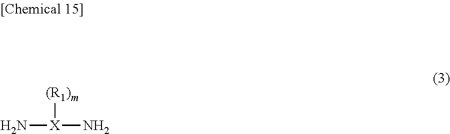

(X, R₁, and m in General Formula (3) have the same definition as X, R₁, and m in General Formula (1).)

Hereinafter, each step will be described.

(Step 1)

In the step 1, a carboxylic acid compound represented by General Formula (2) is activated, thereby obtaining an activated carboxylic acid material.

That is, in the step 1, the carboxyl group contained in the carboxylic acid compound represented by General Formula (2) is activated so that the reactivity of the carboxylic acid compound with an amine compound is improved.

Examples of one aspect of the step 1 include an aspect in which a halogenation treatment is performed on the carboxylic acid compound represented by General Formula (2) so that an acid halide is obtained.

That is, the carboxylic acid compound represented by General Formula (2) is subjected to any of a fluorination treatment, a chlorination treatment, a bromination treatment, and an iodination treatment, so that the carboxylic acid compound is converted into any of an acid fluoride, an acid chloride, an acid bromide, and an acid iodide.

Among these, in view of ease of availability of reactants to be used and the like, for example, an aspect in which a chlorination treatment is performed is preferable.

As the reactant used in the fluorination treatment, known substances can be adopted. For example, it is possible to adopt fluorine, alkali metal fluorides such as potassium fluoride and lithium fluoride, alkaline earth metal fluorides such as calcium fluoride, and quaternary ammonium fluorides such as tetrabutylammonium fluoride.

As the reactant used in the chlorination treatment, known substances can be adopted. For example, it is possible to adopt chlorine, thionyl chloride, oxalyl chloride, phosphorus trichloride, and the like.

As the reactant used in the bromination treatment, known substances can be adopted. For example, bromine and aluminum tribromide can be adopted.

As the reactant used in the iodination treatment, known substances can be adopted. For example, it is possible to adopt iodine, an alkali metal iodide such as potassium iodide, and [bis(trifluoroacetoxy)iodo]benzene.

The conditions under which these reactants are used may be arbitrarily set depending on the reactants to be adopted. It is preferable to adopt conditions under which the proportion of the carboxylic acid compound represented by General Formula (2) that can be converted into an acid halide is equal to or more than 90%.

Examples of another aspect of the step 1 include an aspect in which the carboxylic acid compound represented by General Formula (2) is reacted with a compound having a hydroxyl group so that an ester compound is obtained.

As the compound having a hydroxyl group, a known alcohol compound can be adopted. It is possible to adopt compounds such as methanol, ethanol, isopropanol, n-butanol, t-butyl alcohol, and n-pentanol.

As the compound having a hydroxyl group, for example, 1-hydroxybenzotriazole or a 1-hydroxybenzotriazole derivative can also be used.

For obtaining the ester compound, for example, it is possible to use a condensing agent that is generally used for synthesizing an ester, such as dicyclohexylcarbodiimide.

The aforementioned ester compound can also be obtained by adding an acid catalyst such as hydrochloric acid, sulfuric acid, benzenesulfonic acid, or toluenesulfonic acid, then performing heating, and allowing the reaction to proceed while removing water generated from the alcohol compound and the carboxylic acid compound so that esterification proceeds.

The conditions of esterification may be arbitrarily set depending on the reactants to be adopted. It is preferable to adopt conditions under which the proportion of the carboxylic acid compound represented by General Formula (2) that can be converted into an ester compound is equal to or more than 90%.

(Step 2)

Subsequently, the amine compound represented by General Formula (3) is allowed to act on the activated carboxylic acid material (the acid halide or the ester compound) obtained by the step 1, thereby obtaining an amide bond-containing precursor.

The temperature conditions and time conditions for conversion to the amide bond-containing precursor can be appropriately set depending on the type of the activated carboxylic acid material or the amine compound.

From the viewpoint of accelerating the reaction, known catalysts can also be added as appropriate.

(Solvent)

In the method for manufacturing a photosensitive resin composition of the present embodiment, at least either the step 1 or the step 2 described above is performed in a solvent containing a carbonyl group-containing heterocyclic compound.

It is presumed that there may be a difference in reactivity of monomer molecules between a solvent having a carbonyl group-containing heterocyclic compound and a solvent composed of the conventional acyclic compound, although the details thereof are still unclear. Usually, in the process of synthesizing a photosensitive resin, an acid anhydride as an end-cap compound for terminating the reaction is reacted with the terminal amide group. On the other hand, in a case where the solvent having a carbonyl group-containing heterocyclic compound of the present embodiment is used, the reaction between the acid anhydride as an end-cap compound and the terminal amide group is appropriately controlled, which improves the reaction rate of the terminal.

Furthermore, it is considered that in a case where a solvent having a carbonyl group-containing 5-membered heterocycle is used, the reactivity between the monomer molecules of the photosensitive resin may be appropriately controlled as well, and the molecular weight can be easily increased.

Particularly, in a case where a 5-membered heterocycle is selected as the carbonyl group-containing heterocyclic compound, the obtained action and effect described above can be marked.

The carbonyl group-containing heterocyclic compound exhibits a high dissolving ability to the amide bond-containing precursor or other resin components and has appropriate polarity. Therefore, this compound makes it possible for the reaction in the above step 1 or step 2 to proceed smoothly.

In the step 1 and the step 2, the same solvent or different solvents may be used. From the viewpoint of improving productivity and reaction efficiency, it is preferable to use the same solvent.

Examples of the carbonyl group-containing heterocyclic compound include a 4-membered ring, a 5-membered ring, a 6-membered ring, a 7-membered ring, and the like. Among these, a 5-membered ring is preferable. These carbonyl group-containing heterocyclic compounds may be partially substituted with a hydrocarbon group such as a methyl group, an ethyl group, or a propyl group.

Examples of the carbonyl group-containing heterocyclic compound include a compound containing a nitrogen atom in addition to the heterocycle (hereinafter, this compound will be called “carbonyl group-containing heterocyclic compound (i) having a nitrogen atom”) Using the carbonyl group-containing heterocyclic compound (i) having a nitrogen atom in the photosensitive resin composition of the present embodiment makes it possible to obtain better reactivity and to reduce residues at an opening portion by appropriate solubility.

The heterocycle in the aforementioned carbonyl group-containing 5-membered heterocycle is preferably one kind of compound or two or more compounds selected from furan, pyrrole, imidazole, oxazole, thiazole, and pyrazole. From the viewpoint of improving reaction efficiency, the heterocycle is more preferably one kind of compound or two or more kinds of compounds selected from pyrrole, imidazole, oxazole, thiazole, and pyrazole. Furthermore, different kinds of heterocycles may be combined.

Specifically, examples of the carbonyl group-containing furan include y-butyrolactone. Examples of the carbonyl group-containing pyrrole include N-ethyl-2-pyrrolidone. Examples of the carbonyl group-containing imidazole include 1,3-dimethyl-2-imidazolidinone. Examples of the carbonyl group-containing oxazole include 3-methyl-2-oxazolidone.

Among these, N-ethyl-2-pyrrolidone, 3-methyl-2-oxazolidone, and the like are an example of the carbonyl group-containing heterocyclic compound (i) having a nitrogen atom.

From the viewpoint of increasing the molecular weight of the photosensitive resin and enhancing the reactivity of the photosensitive resin with the end cap, it is preferable to select at least one of y-butyrolactone and 3-methyl-2-oxazolidone.

As the solvent of the present embodiment, different kinds of solvents may be used in combination. For example, different kinds of carbonyl group-containing heterocyclic compounds may be used in combination, different kinds of carbonyl group-containing heterocyclic compounds (i) having a nitrogen atom may be used in combination, or a solvent other than the carbonyl group-containing heterocyclic compound may be used.

That is, as the solvent used in any of the step 1 and the step 2, in addition to the aforementioned carbonyl group-containing heterocyclic compound, a compound that is generally used as a solvent can also be used.

As the solvent to be additionally used, a known solvent can be used. From the viewpoint of enhancing reactivity and obtaining excellent solubility, a heterocyclic compound (ii) that does not have a carbonyl group but has a nitrogen atom in addition to the heterocycle and a compound (iii) that has a nitrogen atom and a carbonyl group are suitably used.

From the viewpoint of maintaining excellent solubility, for example, the carbonyl group-containing heterocyclic compound (i) having a nitrogen atom and the heterocyclic compound (ii) that does not have a carbonyl group but has a nitrogen atom in addition to the heterocycle may be used in combination, or the carbonyl group-containing heterocyclic compound (i) having a nitrogen atom and the compound (iii) having a nitrogen atom and a carbonyl group may be used in combination.

In a case where solvents are mixed together, as for the mixing ratio, the ratio of a compound other than the carbonyl group-containing heterocyclic compound to 100 parts by weight of the carbonyl group-containing heterocyclic compound of the present embodiment is preferably 1 to 40 parts by weight, and more preferably 1 to 30 parts by weight.

Specific examples of such a compound include 2,6-lutidine, pyruvate, N,N-dimethylacetamide,

3-methoxy-N,N-dimethylpropionamide, dimethylsulfoxide, diethylene glycol dimethyl ether, diethylene glycol diethyl ether, diethylene glycol dibutyl ether, propylene glycol monomethyl ether, dipropylene glycol monomethyl ether, propylene glycol monomethyl ether acetate, methyl lactate, ethyl lactate, butyl lactate, methyl-1,3-butylene glycol acetate, 1,3-butylene glycol-3-monomethyl ether, methyl pyruvate, ethyl pyruvate, methyl-3-methoxypropionate, and the like.

In the present embodiment, the aforementioned carbonyl group-containing heterocyclic compound is used as a solvent in the step 1 or the step 2. However, unless the object of the invention is impaired, N-methyl-2-pyrrolidone can be added to the solvent.

The content of N-methyl-2-pyrrolidone with respect to the total amount of solvents is preferably equal to or less than 80% by mass, more preferably equal to or less than 60% by mass, even more preferably equal to or less than 40% by mass, still more preferably equal to or less than 20% by mass, and particularly preferably equal to or less than 5% by mass. It is most especially preferable that the solvent substantially do not include N-methyl-2-pyrrolidone.

“Substantially do not include” means that an aspect in which N-methyl-2-pyrrolidone is intentionally added to the solvent is excluded while an aspect in which N-methyl-pyrrolidone is unavoidably intermixed in the manufacturing process is accepted.

In the present embodiment, it is preferable that both the step 1 and the step 2 described above be performed in a solvent containing a carbonyl group-containing heterocyclic compound.

In a case where the steps 1 and 2 are performed in such a solvent, the process can be simplified, and sometimes both the step 1 and the step 2 can be performed in one pot.

In the present embodiment, an amide bond-containing precursor is obtained at the stage where the step 2 has finished.

For the precursor, by substituting the solvent used in the step 2 with another solvent, using the solvent used in the step 2 as it is, or diluting the solvent used in the step 2 separately, it is possible to obtain a photosensitive resin composition.

(Other Components)

In the present embodiment, in addition to the components described above, various components that are used as photosensitive resin compositions can be mixed in.

For example, as an alkali-soluble resin, a component other than the amide bond-containing precursor can be additionally used.

Examples of such an alkali-soluble resin include a phenol resin, a phenol aralkyl resin, a hydroxystyrene resin, an acrylic resin such as methacrylic acid resin or methacrylic acid ester resin, a cyclic olefin resin, and the like.

In a case where the photosensitive resin composition is used as a so-called positive photosensitive resin composition, for example, photoacid generators including a photosensitive diazoquinone compound, an onium salt such as a diaryliodonium salt, a triarylsulfonium salt, or a sulfonium-borate salt, a 2-nitrobenzyl ester compound, a N-iminosulfonate compound, an imidosulfonate compound, a 2,6-bis(trichloromethyl)-1,3,5-triazine compound, and a dihydropyridine compound can be mixed in.

In addition, as necessary, additives such as an antioxidant, a filler, a surfactant, a photopolymerization initiator, an end capping agent, and a sensitizer may be added.

These may be added in any amount.

(Use)

The photosensitive resin composition obtained by the present embodiment can form a resin film by curing. The obtained resin film can compose, for example, a permanent film such as a protection film, an interlayer film, or a dam material. An electronic device including the resin film as a permanent film can be improved in terms of durability and the like.

Next, an example of an electronic device 100 to which the photosensitive resin composition of the present embodiment is applied will be described.

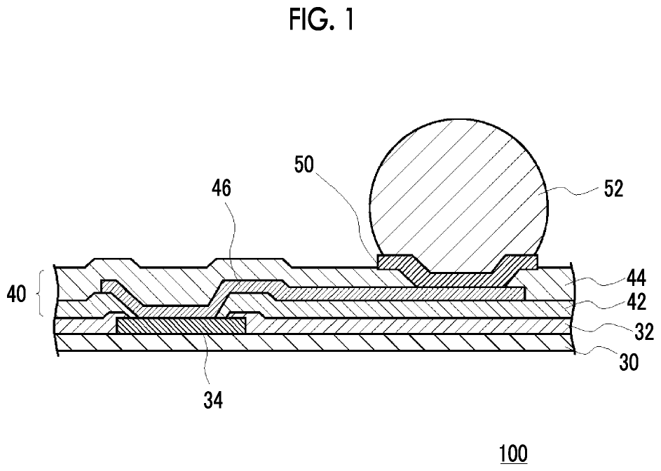

The electronic device 100 shown in FIG. 1 is, for example, a semiconductor chip. In this case, for example, mounting the electronic device 100 on a wiring substrate via a bump 52 makes it possible to obtain a semiconductor package. The electronic device 100 includes a semiconductor substrate provided with a semiconductor element such as a transistor, and a multi layered wiring layer provided on the semiconductor substrate (not shown in the drawing). The uppermost layer of the multilayered wiring layer is provided with an interlayer insulating film 30 and an uppermost wiring layer 34 provided on the interlayer insulating film 30. The uppermost wiring layer 34 is composed, for example, of Al. A passivation film 32 is provided on the interlayer insulating film 30 and the uppermost wiring layer 34. Apart of the passivation film 32 is provided with an opening through which the uppermost wiring layer 34 is exposed.

A rewiring layer 40 is provided on the passivation film 32. The rewiring layer 40 includes an insulating layer 42 provided on the passivation film 32, a rewiring 46 provided on the insulating layer 42, and an insulating layer 44 provided on the insulating layer 42 and the rewiring 46. An opening connected to the uppermost wiring layer 34 is formed in the insulating layer 42. The rewiring 46 is formed on the insulating layer 42 and in the opening provided in the insulating layer 42 and connected to the uppermost wiring layer 34. The insulating layer 44 is provided with an opening connected to the rewiring 46.

In the present embodiment, one or more of the passivation film 32, the insulating layer 42, and the insulating layer 44 can be composed, for example, of a resin film formed by curing the aforementioned photosensitive resin composition. In this case, for example, by patterning a coating film formed of a photosensitive resin material by means of exposing the coating film to ultraviolet rays and developing the coating film and then heating and curing the patterned coating film, the passivation film 32 and the insulating layer 42 or the insulating layer 44 are formed.

A bump 52 is formed in the opening provided in the insulating layer 44, for example, via Under Bump Metallurgy (UBM)) layer 50. The electronic device 100 is connected to a wiring substrate or the like, for example, via the bump 52.

The present invention is not limited to the embodiments described above. As long as the object of the present invention can be achieved, the present invention includes modification, amelioration, and the like.

### EXAMPLE

Next, the present invention will be described based on examples, but the present invention is not limited to the examples.

### Example 1

By the following procedure, an amide bond-containing precursor was obtained using a solvent 1 at the ratio shown in Table 1. The procedure is specifically described below. For the obtained amide bond-containing precursor, the weight-average molecular weight (Mw) and the number-average molecular weight (Mn) were measured. The results are shown in Table 1.

Diphenyl ether-4,4′-dicarboxylic acid (258.2 g, 1 mol) and 270.3 g (2 mol) of 1-hydroxybenzotriazole were dissolved in the solvent 1 (1,500 g). Then, 412.7 g (2 mol) of dicyclohexyl carbodiimide dissolved in the solvent 1 (412 g) was added dropwise thereto for 2 hours at an internal temperature kept at 0° C. to 5° C. After the dripping ended, the internal temperature was returned to room temperature, and the mixture was further stirred for 12 hours for reaction. After the reaction ended, the precipitated dicyclohexyl carbodiurea was removed by filtration, and 4,000 g of pure water was added dropwise to the obtained filtrate so that crystals were precipitated. The crystals were collected by filtration, washed with 8,000 ml of isopropyl alcohol, and then dried in a vacuum, thereby obtaining 467 g of a dicarboxylic acid derivative.

The obtained dicarboxylic acid derivative (40.87 g, 0.083 mol) and 36.63 g (0.1 mol) of

2,2-bis(3-amino-4-hydroxyphenyl)hexafluoropropane were put in a four-neck separable flask equipped with a thermometer, a stirrer, a raw material inlet, and a dry nitrogen gas introduction tube, the solvent 1 (180.8 g) was added thereto, and the components were dissolved. Then, under a nitrogen stream, the solution was heated to 75° C. by using an oil bath and allowed to react for 12 hours at 75° C. Thereafter, 5.58 g (0.034 mol) of
3,6-endomethylene-1,2,3,6-tetrahydrophthalic anhydride dissolved in the solvent 1 (13.0 g) was added thereto, and the mixture was further stirred for 3 hours and then cooled to room temperature so that the reaction was terminated.

Subsequently, the reaction mixture was filtered and then put in a solution of water/isopropyl alcohol=3/1, the precipitate was collected by filtration, thoroughly washed with water, and then dried in a vacuum, thereby obtaining an amide bond-containing precursor having a repeating unit represented by General Formula (A-1) (a resin that turns into polybenzoxazole by going through dehydration and ring closing when heated at 300° C. to 400° C.).

The obtained amide bond-containing precursor had the following repeating unit (A-1).

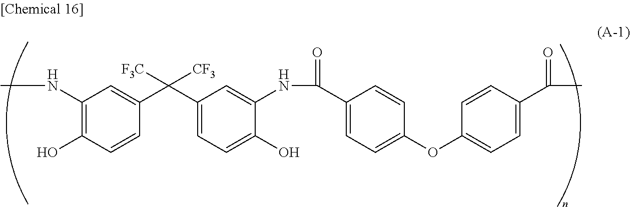

The amide bond-containing precursor obtained as above was dissolved again in the solvent 1, and a photoacid generator was added thereto, thereby obtaining a photosensitive resin composition. The photoacid generator was adjusted so that the amount thereof was 15 parts by mass with respect to 100 parts by mass of the amide bond-containing precursor (A-1). The solvent 1 was adjusted so that the amount thereof was 120 parts by mass with respect to 100 parts by mass of the amide bond-containing precursor (A-1).

### Examples 2 to 12

Amide bond-containing precursors were obtained in the same manner as in Example 1, except that the solvent 1 used in Example 1 was changed to solvents 1 to 6 at the ratios shown in Table 1. For the precursors, Mn and Mw were determined.

Then, the same operation as that in Example 1 was performed, thereby obtaining photosensitive resin compositions.

TABLE 1

| | Mixing ratio of solvent (weight ratio) | | | | | | Amide bond-containing precursor | | |
|---|---|---|---|---|---|---|---|---|---|
| | Solvent 1 | Solvent 2 | Solvent 3 | Solvent 4 | Solvent 5 | Solvent 6 | Mn | Mw | Mw/Mn |
| Example 1 | 100 | | | | | | 8,700 | 13,500 | 1.55 |
| Example 2 | | 100 | | | | | 8,800 | 13,100 | 1.49 |
| Example 3 | | | | 100 | | | 9,900 | 15,900 | 1.61 |
| Example 4 | 85 | | 15 | | | | 9,000 | 14,300 | 1.58 |
| Example 5 | 70 | | | 30 | | | 8,900 | 14,000 | 1.57 |
| Example 6 | 30 | | | 70 | | | 9,400 | 14,900 | 1.59 |
| Example 7 | 50 | 50 | | | | | 8,750 | 13,300 | 1.52 |
| Example 8 | 85 | | | | 15 | | 8,700 | 13,000 | 1.49 |
| Example 9 | | 10 | | 90 | | | 9,750 | 15,600 | 1.60 |
| Example 10 | | | 15 | 85 | | | 9,200 | 14,400 | 1.56 |
| Example 11 | | 90 | | 10 | | | 8,800 | 13,300 | 1.51 |
| Example 12 | | 95 | | | | 5 | 8,900 | 13,300 | 1.49 |

The solvents 1 to 6 are as follows.

Solvent 1: N-ethyl-2-pyrrolidone

Solvent 2: 3-methyl-2-oxazolidone

Solvent 3: 3-methoxy-N,N-dimethylpropionamide

Solvent 4: y-butyrolactone

Solvent 5: 2,6-lutidine

Solvent 6: dimethyl sulfoxide

For each of the photosensitive resin compositions of Examples 1 to 12, patterning properties were checked. As a result, it was found that all of the photosensitive resin compositions have patterning properties as good as the patterning properties of the conventional photosensitive resin composition.

As shown in this example, using a specific solvent makes it possible to obtain a desired amide bond-containing precursor. Furthermore, preparing a photosensitive resin composition by using the precursor makes it possible to stably obtain a photosensitive resin composition that imposes less environmental load.

This application claims priority on the basis of Japanese Patent Application No. 2020-026930 filed on Feb. 20, 2020, the entire disclosure of which is incorporated into the present specification.

### REFERENCE SIGNS LIST

100 electronic device
30 interlayer insulating film
32 passivation film
34 uppermost wiring layer
40 rewiring layer
42 insulating layer
44 insulating layer
46 rewiring
50 UBM layer
52 bump

1. A method for manufacturing a photosensitive resin composition containing an amide bond-containing precursor having a repeating unit represented by General Formula (1), the method comprising:
a step of obtaining an activated carboxylic acid material by activating a carboxylic acid compound represented by General Formula (2); and
a step of obtaining the amide bond-containing precursor by allowing an amine compound represented by General Formula (3) to act on the activated carboxylic acid material,
wherein at least either the step of obtaining an activated carboxylic acid material or the step of obtaining an amide bond-containing precursor is performed in a solvent containing a carbonyl group-containing heterocyclic compound, 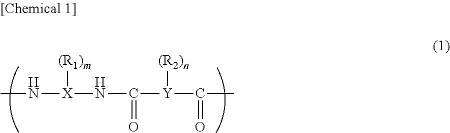
(in General Formula (1), each of X and Y is an organic group, R₁ is a hydroxyl group, —O—R₃, an alkyl group, an acyloxy group, or a cycloalkyl group, a plurality of R₁'s may be the same as or different from each other in a case where the repeating unit has the plurality of R₁'s, R₂ is a hydroxyl group, a carboxyl group, —O—R₃, or —COO—R₃, a plurality of R₂'s may be the same as or different from each other in a case where the repeating unit has the plurality of R₂'s, R₃ in R₁ and R₂ is an organic group having 1 to 15 carbon atoms, at least one of R₂'s is a carboxyl group in a case where there is no hydroxyl group as R₁, at least one of R₁'s is a hydroxyl group in a case where there is no carboxyl group as R₂, m is an integer of 0 to 8, and n is an integer of 0 to 8), 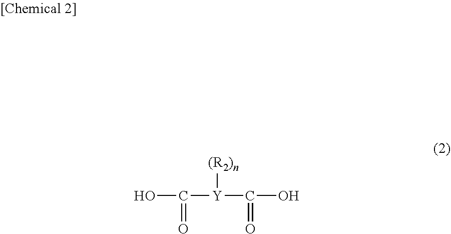
(Y, R₂, and n in General Formula (2) have the same definition as Y, R₂, and n in General Formula (1)), 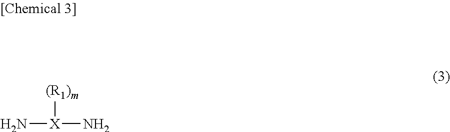
(X, R₁, and m in General Formula (3) have the same definition as X, R₁, and m in General Formula (1).)

2. The method for manufacturing a photosensitive resin composition according to claim 1,
wherein the step of obtaining an activated carboxylic acid material is a step of obtaining an acid halide by performing a halogenation treatment on the carboxylic acid compound represented by General Formula (2).

3. The method for manufacturing a photosensitive resin composition according to claim 2,
wherein the halogenation treatment is a chlorination treatment.

4. The method for manufacturing a photosensitive resin composition according to claim 1,
wherein the step of obtaining an activated carboxylic acid material is performed by reacting the carboxylic acid compound represented by General Formula (2) with a compound having a hydroxyl group to obtain an ester compound.

5. The method for manufacturing a photosensitive resin composition according to claim 4,
wherein the compound having a hydroxyl group is 1-hydroxybenzotriazole or a 1-hydroxybenzotriazole derivative.

6. The method for manufacturing a photosensitive resin composition according to claim 1,
wherein both the step of obtaining an activated carboxylic acid material and the step of obtaining an amide bond-containing precursor are performed in the solvent containing a carbonyl group-containing heterocyclic compound.

7. The method for manufacturing a photosensitive resin composition according to claim 1,
wherein the carbonyl group-containing heterocycle is one kind of compound or two or more kinds of compounds selected from furan, pyrrole, imidazole, oxazole, thiazole, and pyrazole.
